(19) United States
(12) Patent Application Publication
(10) Pub. No.: US 2010/0307552 A1
(43) Pub. Date: Dec. 9, 2010

(54) METHODS FOR COATING A SUBSTRATE

(75) Inventors: Glenn Eric Kohnke, Corning, NY (US); Jia Liu, Painted Post, NY (US)

Correspondence Address: CORNING INCORPORATED, SP-TI-3-1, CORNING, NY, 14831, US

(73) Assignee: Corning Incorporated

(21) Appl. No.: 12/517,331

(22) PCT Filed: Mar. 25, 2009
(86) PCT No.: PCT/US09/01880

§ 371 Date: Jun. 2, 2009

Related U.S. Application Data
(60) Provisional application No. 61/039,398, filed on Mar. 25, 2008.

(51) Int. Cl. H01L 31/00; B05D 3/02; H01L 21/46; H01L 21/36; B32B 5/16; G02B 5/02

(52) U.S. Cl. 136/243; 427/372.2; 438/758; 438/478; 428/143; 359/599; 257/E21.461; 257/E21.482

(57) ABSTRACT

Coated substrates and methods for coating substrates, for example, a self-assembly method, disclosed herein are useful for, for example, photovoltaic cells.

This application claims the benefit of priority to U.S. Provisional Patent Application 61/039,398 filed on Mar. 25, 2008 and the PCT Application PCT/US09/01880 filed on Mar. 25, 2009.

### BACKGROUND

1. Field of the Disclosure

Embodiments relate generally to coated substrates and methods for coating substrates, and more particularly to coated substrates and methods for coating substrates useful for, for example, photovoltaic cells.

2. Technical Background

Thin films of both micro and nano sized particles are of technological interest. Such films can provide new and different properties to articles coated therewith, including chemical, optical and electronic properties, as well as various surface properties. Examples of articles that include coatings to provide desired properties include photonic crystals; lasers formed of two-dimensional assemblies of colloidal particles; films for altering surface properties such as conductivity on composite substrates for sensor applications; waveguides; coatings for modifying wetting properties; and surface enhanced raman spectroscopy (SERS) substrates.

Methods of forming micro and nano sized particle coatings are many and varied. Most of the conventional methods however have limited practical applications because of small sample sizes, slow coating rates, difficulty in controlling the coating thickness, the need for complex equipment, or a combination of these problems.

It would be advantageous to have a method for coating a substrate wherein a monolayer of particles could be formed on the substrate. Further, it would be advantageous for the coating method to be adaptable for large substrates and adaptable to a continuous coating process.

### SUMMARY

Methods for coating substrates, as described herein, address one or more of the above-mentioned disadvantages of conventional coating methods.

One embodiment is a coating method comprising providing a coating mixture comprising inorganic structures and a liquid carrier, forming a coating layer of the coating mixture on a surface of a liquid subphase, immersing at least a portion of a substrate in the liquid subphase, separating the substrate from the liquid subphase to transfer at least a portion of the coating layer to the substrate to form a coated substrate, and heating at least a portion of the coated substrate.

Another embodiment is a coating method comprising providing a coating mixture comprising structures and a liquid carrier, forming a coating layer of the coating mixture on a surface of a liquid subphase, immersing at least a portion of a substrate in the liquid subphase, separating the substrate from the liquid subphase to transfer at least a portion of the coating layer to the substrate to form a coated substrate, and heating at least a portion of the coated substrate.

Yet another embodiment is an article comprising a sintered monolayer of structures selected from spheres, microspheres, bodies, particles, aggregated particles, and combinations thereof on a substrate.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is a schematic of features of a coating method according to one embodiment.

FIG. 2 is optical microscope image of a bilayer of silica on sapphire made according to one embodiment.

FIG. 3, FIG. 4, FIG. 5, and FIG. 6 are graphs showing the scattering characteristics of a sample made, according to one embodiment, with an additional transmitting conductive oxide layer.

FIG. 7 is a graph of total and diffuse transmittance of the sample in FIGS. 3 through 6.

FIG. 8 is a graphical comparison of Si absorptance versus wavelength for a Si-coated textured substrate, according to one embodiment, and a non-textured substrate.

FIG. 9a and FIG. 9b are scanning electron microscope (SEM) images of sintered borosilicate microspheres (d50=1.6 microns, 830 degrees Celcius) on EagleXG™ glass.

FIG. 10a and FIG. 10b are scanning electron microscope (SEM) images of sintered borosilicate microspheres (d50=1.8 microns, 830 degrees Celcius) on EagleXG™ glass.

FIG. 11a and FIG. 11b are scanning electron microscope (SEM) images of before sintering and after sintering, respectively, of borosilicate microspheres (d50=1.6 microns, 870 degrees Celcius) on EagleXG™ glass.

FIG. 12 is an optical microscope image of soda lime microspheres (d50=1.9 microns, 650 degrees Celcius) on EagleXG™ glass.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

As used herein, the term “hydrophobic” generally has the meaning given it by those of skill in the art. Specifically, hydrophobic means antagonistic to water, mostly incapable of dissolving in water in any appreciable amount or being repelled from water or not being wetted by water.

As used herein, the term “hydrophilic” generally has the meaning given it by those of skill in the art. Specifically, hydrophilic means having a strong tendency to bind or absorb water, or the ability to transiently bind to water or be easily dissolved in water or other polar solvents or being wetted by water.

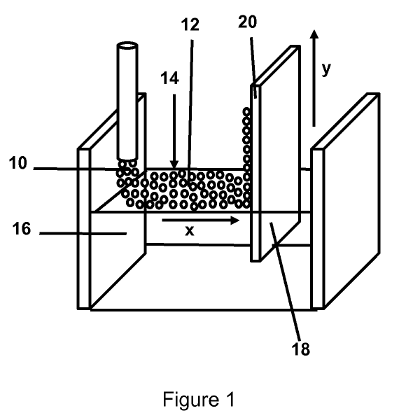

One embodiment, is a coating method, features of which are shown in FIG. 1, comprising providing a coating mixture 10 comprising inorganic structures and a liquid carrier, forming a coating layer 12 of the coating mixture on a surface 14 of a liquid subphase 16, immersing at least a portion of a substrate 18 in the liquid subphase, separating the substrate from the liquid subphase arrow y to transfer at least a portion of the coating layer to the substrate to form a coated substrate 20, and heating at least a portion of the coated substrate.

Another embodiment is a coating method comprising providing a coating mixture comprising structures and a liquid carrier, forming a coating layer of the coating mixture on a surface of a liquid subphase, immersing at least a portion of a substrate in the liquid subphase, separating the substrate from the liquid subphase to transfer at least a portion of the coating layer to the substrate to form a coated substrate, and heating at least a portion of the coated substrate.

According to one embodiment, the substrate is an inorganic substrate. The inorganic substrate, in one embodiment, comprises a material selected from a glass, a ceramic, a glass ceramic, sapphire, silicon carbide, a semiconductor, and combinations thereof.

In another embodiment, the substrate is an organic substrate. The organic substrate, in one embodiment comprises a material selected from a polymer, polystyrene, polymethylmethacrylate (PMMA), a thermoplastic polymer, a thermoset polymer, and combinations thereof.

In one embodiment, the structures comprise spheres, microspheres, bodies, particles, aggregated particles, or combinations thereof. In one embodiment, the structures can be of any shape or geometric shape, for example, polygonal. The structures can be organic, inorganic, or combinations thereof and can comprise a material selected from a glass, a ceramic, a glass ceramic, sapphire, silicon carbide, a semiconductor, a polymer, polystyrene, polymethylmethacrylate (PMMA), a thermoplastic polymer, a thermoset polymer, and combinations thereof.

Generally, any size structures that are generally used by those of skill in the art can be utilized herein. As structures become larger, heavier, or both the ability of the structures to be maintained on the surface of the subphase liquid decreases. This can cause the structures to fall into the subphase liquid and therefore not be able to be coated onto a substrate. This can be compensated for, partially or fully, by increasing the surface tension of the liquid subphase. In one embodiment, the structures have diameters of 20 micrometers (μm) or less, for example, in the range of from 100 nanometers (nm) to 20 μm, for example, 1 μm to 10 μm can be coated using methods disclosed herein.

In one embodiment, the structures have a distribution of sizes, such as diameter. The diameter dispersion of structures is the range of diameters of the structures. Structures can have monodisperse diameters, polydisperse diameters, or a combination thereof. Structures that have a monodisperse diameter have substantially the same diameter. Structures that have polydisperse diameters have a range of diameters distributed in a continuous manner about an average diameter. Generally, an average size of polydisperse structures is reported as the particle size. Such structures will have diameters that fall within a range of values.

According to one embodiment, one or more monodisperse structures can also be utilized. In an embodiment, structures having two different monodisperse diameters can be utilized. In an embodiment, monodisperse structures that are large can be utilized in combination with monodisperse structures that are small. Such an embodiment can be advantageous since smaller structures can fill voids between larger structures. An example of two different monodisperse particle sizes that could be utilized include, monodisperse structures having a diameter of 10.5 μm and monodisperse structures having a diameter of 0.1 μm.

In one embodiment, the mixture is a suspension or a dispersion comprising a liquid carrier and structures comprising an inorganic material, an organic material, or combinations thereof.

The liquid carrier can generally be chosen with properties such that it will not accumulate on the subphase. Properties that may be relevant to the ability of the liquid carrier to not accumulate on the subphase liquid include, but are not limited to, the miscibility of the liquid carrier with the subphase, and the vapor pressure of the liquid carrier.

In an embodiment, the liquid carrier can be chosen to be miscible or at least partially miscible in the subphase. In an embodiment, the liquid carrier can be chosen to have a relatively high vapor pressure. The liquid carrier can also be chosen as one that can easily be recovered from the subphase. The liquid carrier can also be chosen as one that is not considered environmentally or occupationally hazardous or undesirable. In an embodiment, the liquid carrier can be chosen based on one of, more than one of, or even all of the above noted properties. In some instances, properties other than those discussed herein may also be relevant to the choice of liquid carrier.

In an embodiment, the liquid carrier can be, for example, a single solvent, a mixture of solvents, or a solvent (a single solvent or a mixture of solvents) having other non-solvent components. Exemplary solvents that can be utilized include, but are not limited to, a hydrocarbon, a halogenated hydrocarbon, an alcohol, an ether, a ketone, and like substances, or mixtures thereof, such as 2-propanol (also referred to as isopropanol, IPA, or isopropyl alcohol), tetrahydrofuran (THF), ethanol, chloroform, acetone, butanol, octanol, pentane, hexane, cyclohexane, and mixtures thereof. In an embodiment where the subphase is a polar liquid (such as water), exemplary liquid carriers that can be utilized include, but are not limited to, 2-propanol, tetrahydrofuan, and ethanol for example. Non-solvent components that can be added to a solvent to form the liquid carrier include, but are not limited to, dispersants, salts, and viscosity modifiers. According to one embodiment, the liquid subphase comprises a material selected from water, heavy water (D₂O), an aqueous salt solution, combinations thereof.

In one embodiment, heating comprises sintering at least a portion of the coated substrate, at least a portion of the structures, or a combination thereof. The entire coated substrate can also be heated such that substantially all of the inorganic structures are sintered. Heating can be realized by localized heating such as by using a laser, by radiant or convection heating such as by using a furnace, or by using a flame, or by using a combination of localized and radiant or convection or flame heating. One embodiment comprises heating the coated substrate as the coated substrate is being formed. For example, a self-assembled monolayer already transferred on a portion of the substrate can be heated with a laser while self-assembly is occurring on another portion of the substrate.

The method further comprises, according to one embodiment, affecting the hydrophobicity of the structures prior to forming the coating layer.

In one embodiment, the coating layer has a substantially unitary direction of flow arrow x, shown in FIG. 1, toward the substrate.

The substrate can comprise one or more layers, according to one embodiment. For example, the substrate could comprise one or more layers of inorganic, organic, or a combination of inorganic and/or organic materials.

Separating the substrate from the liquid subphase to transfer at least a portion of the coating layer to the substrate to form a coated substrate, in one embodiment, comprises forming a monolayer of the inorganic structures on the substrate.

In one embodiment, immersing at least a portion of an substrate in the liquid subphase comprises immersing at least a portion of the substrate in the coating layer.

Light emitting devices, for example, a semiconductor or an organic light emitting diode (OLED) for enhanced light extraction; or optical diffusers for, for example, illumination systems can comprise the coated substrate made according to the methods described herein.

Yet another embodiment is an article comprising a sintered monolayer of structures selected from spheres, microspheres, bodies, particles, aggregated particles, and combinations thereof on a substrate. The structures, in one embodiment, are fused to a surface of the substrate. The structures can be organic, inorganic, or combinations thereof and can comprise a material selected from a glass, a ceramic, a glass ceramic, sapphire, silicon carbide, a semiconductor, a polymer, polystyrene, polymethylmethacrylate (PMMA), a thermoplastic polymer, a thermoset polymer, and combinations thereof.

According to one embodiment, the substrate in the article is an inorganic substrate. The inorganic substrate, in one embodiment, comprises a material selected from a glass, a ceramic, a glass ceramic, sapphire, silicon carbide, a semiconductor, and combinations thereof.

In another embodiment, the substrate in the article is an organic substrate. The organic substrate, in one embodiment comprises a material selected from a polymer, polystyrene, polymethylmethacrylate (PMMA), a thermoplastic polymer, a thermoset polymer, and combinations thereof. In one embodiment, microparticles are assembled into a monolayer film at an air-water interface and are subsequently lifted off onto a substrate.

In one embodiment, the particles comprise spheres, microspheres, bodies, aggregated particles, or combinations thereof. The particles can be organic, inorganic, or combinations thereof and can comprise a material selected from a glass, a ceramic, a glass ceramic, sapphire, silicon carbide, a semiconductor, a polymer, polystyrene, polymethylmethacrylate (PMMA), a thermoplastic polymer, a thermoset polymer, and combinations thereof.

One embodiment is a photovoltaic device comprising the coated substrate made according to the methods disclosed herein. The photovoltaic device, according to one embodiment further comprises a conductive material adjacent to the substrate, and an active photovoltaic medium adjacent to the conductive material.

The active photovoltaic medium, according to one embodiment, is in physical contact with the conductive material. The conductive material, according to one embodiment is a transparent conductive film, for example, a transparent conductive oxide (TCO). The transparent conductive film can comprise a textured surface.

The photovoltaic device, in one embodiment, further comprises a counter electrode in physical contact with the active photovoltaic medium and located on an opposite surface of the active photovoltaic medium as the conductive material.

In one embodiment, a coated substrate is created having a textured surface that is suitable for subsequent deposition of a TCO and thin film silicon photovoltaic device structure. In one embodiment, structure is formed by deposition of glass microparticles or microspheres onto a glass substrate followed by sintering or simultaneous deposition and sintering. In one embodiment, multiple depositions with particles of different size distributions are used to create textures having different texture sizes.

In one embodiment, the glass microstructure is smoothly varying and less likely to create electrical problems within the silicon solar cell device structure. Since, in one embodiment, the glass is transparent over the entire solar spectrum, the thickness of the material can be optimized for light trapping performance without concerns of absorption as in the case of the textured TCO. For non-etched embodiments, there is no need for additional chemical processing. Relative to sintered glass approaches with silica microspheres, the methods disclosed herein can use low cost glass microspheres or simply milled glass microparticles and no binding material is required due to direct sintering of the glass to the substrate. The particle size distribution is easily controlled and enables the creation of a reproducible optimized texture.

### Examples

In a relatively high temperature process, the method began using epitaxial grade, double-side polished sapphire (an inorganic substrate) and fused silica microspheres (inorganic structures). The microspheres in this example were procured from Bangs Laboratories (Fishers, Ind.) and have a narrow size distribution with a mean diameter of 2.47 μm. If the detailed composition of the fused silica (e.g., OH content) is not known, the sintering temperature can be affected. The as-received microspheres are hydrophilic; they were surface-treated with octadecyltrimethoxysilane, to affect their hydrophobicity, and dispersed in isopropanol.

For convenience, the sapphire was diced into 1 cm by 1 cm squares for processing. The substrates were cleaned by ultra-sonication in isopropanol prior to use and were then mounted on a glass microscope slide. A rectangular trough (˜1″ wide and ˜3″ long) was filled with de-ionized water. The microscope slide with sapphire substrates on it was dipped into water in the middle of the trough. The dispersion of silica microspheres was pumped at a rate of 0.5 mL/min using a syringe pump and flowed down the end wall. The dispersion spread on the water surface driven by interfacial tensions. The isopropanol partially dissolved into water and partially evaporated, leaving the surface-treated silica microspheres floating on the water surface and assembling into a close-packed monolayer film.

Once the film began to form, the microscope slide was withdrawn at a 90 degree angle with the water surface at a speed of 0.49 mm/sec. In this manner, the film was transferred onto the substrates while being continuously formed at the addition end. The resulting monolayer of microspheres was allowed to dry under standard room conditions. The sample was then sintered in a high temperature muffle furnace in air with the following furnace schedule:
1. Ramp from room temperature to 1300° C. at a rate of 10° C./minute
2. Hold at 1300° C. for 30 minutes
3. Cool from 1300° C. to room temperature at <10° C./minute

Furnace temperatures from 1260° C. to 1300° C. were investigated resulting in minor variations in appearance and nearly identical optical performance.

Note that initial work was done at higher temperatures in a nitrogen atmosphere before switching to a different furnace at lower temperatures in air.

To characterize the samples, an optical apparatus was assembled to measure the transmission through the substrate as a function of incident angle. To preserve the incident angle of the incoming light, a half-ball sapphire lens was used with index-matching oil between the lens and the back-side (would-be growth side) of the substrate. The light transmitted through the microstructured surface was collected by an integrating sphere and detected. The incident light was provided by a He—Ne laser operating at 632.8 nm. The microstructured glass sample shows enhanced transmission at an incident angle greater than 30 degrees as compared to a bare substrate.

Note that there are other methods for forming self-assembled monolayers of microspheres and they could be applied to this process. There may also be other methods for depositing monolayers or multiple layers of microspheres or microparticles that would result in similar functionality. Sapphire is used as a demonstration and is of most interest for the application of UV LEDs. However, a similar process could be applied to other LED substrates including InP, GaAs, GaP, GaN, and silicon carbide. In cases where the growth temperature is lower than for UV LEDs (1000 to 1200° C.), other glass compositions may be available including those with higher index of refraction than fused silica. This approach does not assist the light emitted from the edges of the substrates which can be significant. For the case of visible LEDs, it is possible to continue to use a silicone around the chip edges to assist with light extraction. The CTE matching requirement of the glass to the substrate is a function of glass thickness. For very thin glass layers as described here, the CTE matching requirement is relaxed. The CTE mismatch will limit the maximum thickness of the glass layer.

In a relatively low temperature process, the method would begin with a double-side polished, epitaxial wafer with the LED structure grown on it as the substrate. Glass microspheres or microparticles would be deposited on the substrate in a manner similar to that described in the method above.

Since the epitaxially grown layers would be degraded by high temperatures, the sintering process should be done at a relatively low temperature (<600° C. and preferably lower). A glass composition that has a glass transition temperature <500° C. is optimum. Also, since one advantage of this process is to use a material with a refractive index higher than silicone for improved light extraction, glasses with refractive indices >1.5, for example, refractive indices >=1.8. A refractive index of 1.8 provides an index match to sapphire which is desirable for blue and UV LEDs. Near-UV transparency is also desired to enable light extraction from LEDs having emission wavelengths in the range of from 380 nm to 390 nm that are of interest for white light generation via UV-pumped phosphors.

Experiments were completed using a bismuth borate glass containing 25 mol % Bi₂O₃ and 75 mol % B₂O₃. The thermal and optical properties of this material are well known. Of interest is the high refractive index (>1.8) and the low glass transition temperature (470° C.) of this glass composition. The CTE of 6.3 ppm/° C. is approximately in between the CTEs of the substrate materials which may be advantageous for blue LEDs: sapphire and silicon carbide.

While self-assembled monolayers were fabricated with this bismuth borate glass on sapphire. And heated at 550° C.

The bismuth borate glass composition was chosen due to a combination of its CTE, refractive index, and glass transition temperature. This appears to make it well suited for the sapphire or silicon carbide application. It has not been optimized for other properties including durability or resistance to devitrification during processing. It is possible that a refined glass composition would be advantageous.

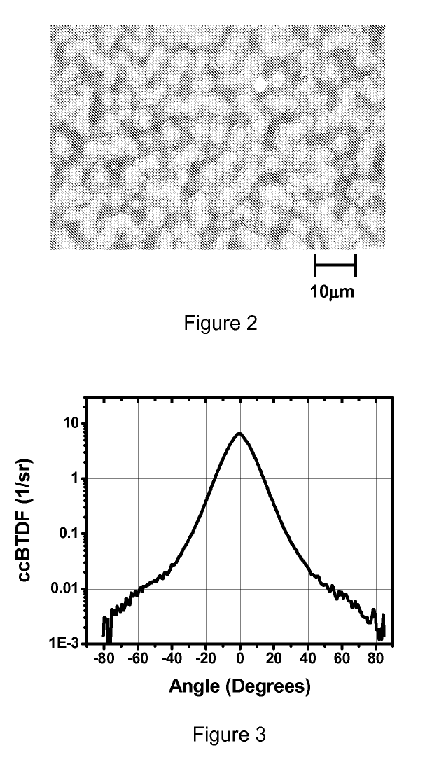

For narrow size distribution microspheres, the self-assembly process can be done multiple times before sintering or repeated after sintering to create more complex microstructures. An example made with 4.8 μm and 1 μm silica microspheres on sapphire is shown in FIG. 2. In this case, the sample was coated with a monolayer of 4.8 μm microspheres, sintered, coated with a monolayer of 1 μm microspheres, and finally sintered a second time. This creates a surface with different feature sizes within the same texture.

This process is scalable in terms of particle size such that smaller feature sizes can be obtained. The simplicity of the self-assembly process enables it to be scaled to large area substrates in principle. In most cases, there is a single sintering step. The features are clearly not as sharp as those in the directly textured TCO suggesting that the electrical and crystal growth issues may be less of a concern. The separation of the texturing from the TCO deposition enables optimization of the texture at the expense of an additional process step. Rounded textures were previously explored for TCO with performance that was not as good as the faceted texture. However, it is not clear what role the TCO absorption played in those results.

There are two additional microsphere parameters that may offer significant advantages in the substrate performance. One is the refractive index of the microspheres. The refractive index of the microspheres is easily tailored by changing the composition. The softening temperature of higher index glasses is typically lower than for low index glasses.

In this case, care must be taken to use glass compositions that allow high enough sintering temperatures such that the textured substrate retains its form during subsequent TCO and silicon processing steps.

The second parameter that may offer an advantage is the use of hollow glass microspheres. Hollow glass microspheres are commonly used in many applications although typically at larger sizes than those desired in this application. The hollow microspheres may offer process advantages if they float on water without functionalization. They also would provide different scattering properties due to the trapped glass/air interface that is expected to be created during the sintering process.

In one embodiment, a textured glass substrate for thin film PV applications is formed by sintering glass microparticles on planar glass substrates where the glass particles were deposited by self assembly, dip coating, electrostatic deposition, etc. In one embodiment, the microparticles are deposited in a single monolayer followed by sintering. In one embodiment, the microparticles are deposited in multiple layers followed by sintering or deposited in multiple layers with sintering in between each layer. In one embodiment, the size distributions of particles are varied in different layers.

In one embodiment, the microparticle size and glass properties are chosen such that the sintering temperature occurs below the softening temperature of the planar glass substrate. In one embodiment, the microparticle size and glass properties are chosen such that the sintering temperature occurs below the strain point temperature of the planar glass substrate. In one embodiment, the sintering temperature occurs above the subsequent TCO and silicon deposition and/or annealing process temperatures. The angle between adjacent structures after heating is greater than 90 degrees, for example, greater than 110 degrees.

In one embodiment, the substrate is formed by simultaneously depositing and sintering the microparticles on the planar glass substrate by depositing cold microparticles on a sufficiently hot substrate or by depositing hot microparticles on a sufficiently hot substrate.

In one embodiment, the microparticles are soda lime or borosilicate glass and the substrate is an aluminosilicate or soda lime glass. In one embodiment, the microparticles are a high index glass (n>1.6). In one embodiment, the microparticles are hollow microspheres.

Many different combinations of glasses and substrates have been made. They include (format: glass/substrate): Silica/Sapphire, Bismuth Borate/Sapphire, Silica/Bismuth, Borate/Sapphire, Borosilicate/EagleXG™, Silica/Boroslicate/EagleXG™, Soda Lime/EagleXG™, Soda Lime/Silica/EagleXG™, Soda Lime/Soda Lime, Sphericel/EagleXG™ Silica/Quartz, Potassium Borosilicate/EagleXG™, and Silica/Potassium Borosilicate/EagleXG™.

In one embodiment, the glass texture is smoothly varying at the submicron level with no facets. In one embodiment, the glass texture has a size distribution in the range of 0.1 to 20 microns and preferably in the range of 0.1 to 5 microns. In one embodiment, the substrate has a transmittance greater than 70% and preferably greater than 80% between 400 nm and 1200 nm. In one embodiment, the substrate has a haze value greater than 60% between 400 nm and 1200 nm.

We subsequently switched to borosilicate microspheres (from Potters Industries, Malvern, Pa.). The as-received particles contained a significant number of large particles (>5 μm) and were filtered by air classification to have a distribution with a d50 (by volume) of 1.6 μm to 1.8 μm. The as-received microspheres are hydrophilic. They were surface-treated with octadecyltrimethoxysilane to make them hydrophobic and dispersed in isopropanol at 10 mg/ml. Eagle™ substrates cut into 1 inch×3 inch sample sizes were used.

The substrates were cleaned by ultra-sonication in acetone and rinsing in ethanol prior to use. A rectangular trough (˜1 inch wide and ˜3 inches long) was filled with de-ionized water. The microscope slide was dipped into water in the middle of the trough. The dispersion of microspheres was pumped at a rate of 0.5 mL/min using a syringe pump and flowed down the end wall. The dispersion spread on the water surface driven by interfacial tensions. The isopropanol partially dissolved into water and partially evaporated, leaving the surface-treated microspheres floating on the water surface and assembling into a close-packed monolayer film. Once the film had formed, the microscope slide was withdrawn at a 90 degrees angle with the water surface at a speed of 0.68 mm/sec. In this manner, the film was transferred onto the substrates while being continuously formed at the addition end.

The resulting monolayer of microspheres was allowed to dry under standard room conditions. The sintering procedure is similar to those previously described:
1. Ramp from room temperature to a temperature of from 830° C. to 870° C. at a rate of 10° C./min
2. Hold at temperature for 60 min
3. Cool to room temperature at <10° C./min

A scattering measurement system was used to characterize the optical scattering of light through the samples into air.

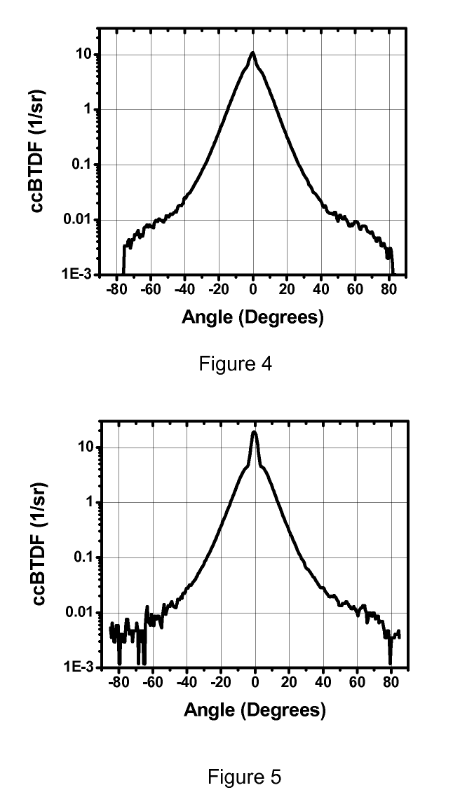

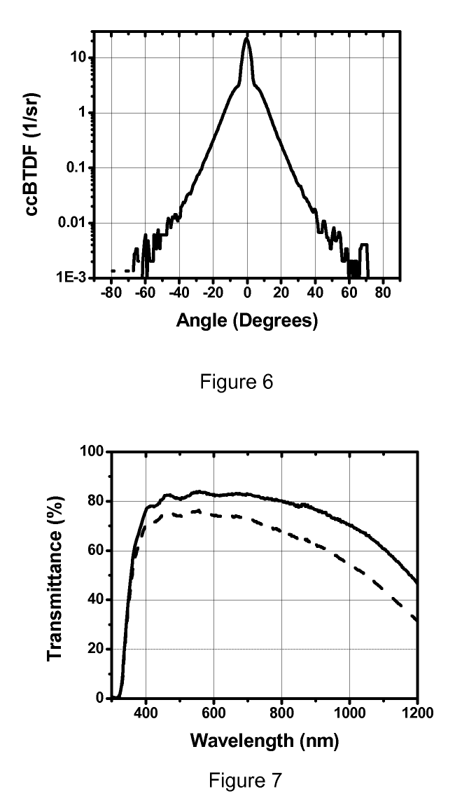

The scattering is characterized by a line scan through a 2-D plot of the cosine-corrected bidirectional transmission function (ccBTDF). The graphs shown in FIG. 3, FIG. 4, FIG. 5, and FIG. 6 show the scattering characteristics of a sample (borosilicate microspheres on EagleXG™) fabricated, according to one embodiment, the self assembly and sintering process with an additional sputtered Aluminum-doped ZnO transmitting conductive oxide thin film layer. The plots in FIG. 3, FIG. 4, FIG. 5, and FIG. 6 are in order of increasing wavelength 400 nm, 600 nm, 800 nm, and 1000 nm, respectively. FIG. 7 is a graph of total and diffuse transmittance of the sample in FIGS. 3 through 6.

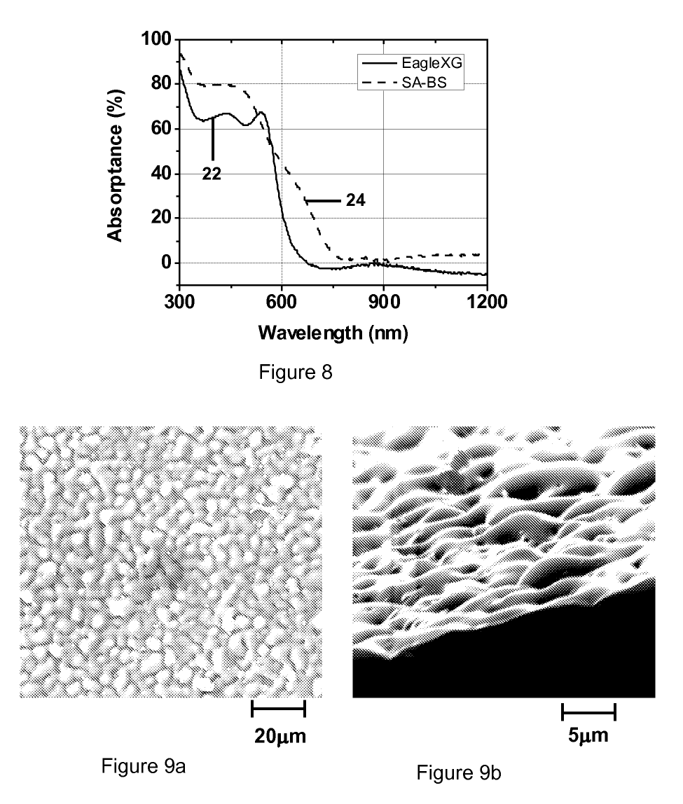

Although PV cells have not yet been fabricated, a surrogate test was developed to analyze the absorption in a thin film of amorphous silicon (a-Si). A thin layer (˜130 nm) of a-Si was deposited on the substrate and on a bare glass substrate. The sample reflectance and transmittance was then measured with a spectrophotometer. The absorptance was measured as A=1-R-T. In the spectral region where the a-Si absorption is decreasing (550-750 nm), light trapping enhancement was observed for the self-assembled and sintered sample. This is illustrated in the graph shown in FIG. 8 where the microstructured glass substrate shown by line 22 is compared to flat EagleXG™, shown by line 24.

To evaluate the surface morphology, SEM analysis has been completed on a variety of sintered samples. The surfaces morphology can be modified over a wide range depending on the sintering conditions (time and temperature) as well as details of the fluid forming process. FIG. 1 is a schematic of features of a coating method according to one embodiment.

FIG. 2 is optical microscope image of a bilayer of silica on sapphire made according to one embodiment.

FIG. 3, FIG. 4, FIG. 5, and FIG. 6 are graphs showing the scattering characteristics of a sample made, according to one embodiment, with an additional transmitting conductive oxide layer.

FIG. 7 is a graph of total and diffuse transmittance of the sample in FIGS. 3 through 6.

FIG. 8 is a graphical comparison of Si absorptance versus wavelength for a Si-coated textured substrate, according to one embodiment, and a non-textured substrate.

FIG. 9a and FIG. 9b are scanning electron microscope (SEM) images of sintered borosilicate microspheres (d50=1.6 microns, 830 degrees Celcius) on EagleXG™ glass.

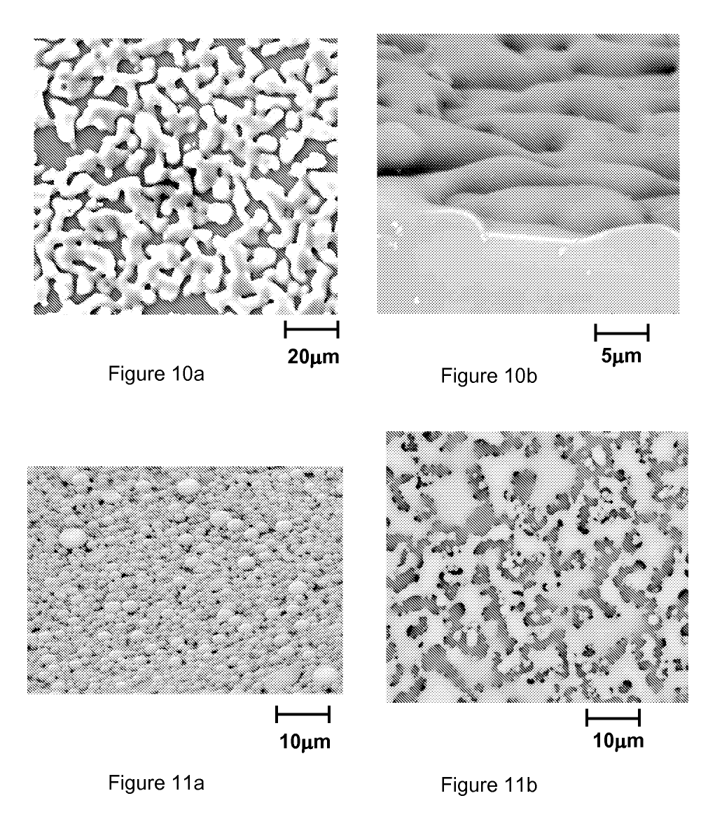

FIG. 10a and FIG. 10b are scanning electron microscope (SEM) images of sintered borosilicate microspheres (d50=1.8 microns, 830 degrees Celcius) on EagleXG™ glass.

FIG. 11a and FIG. 11b are scanning electron microscope (SEM) images of before sintering and after sintering, respectively, of borosilicate microspheres (d50=1.6 microns, 870 degrees Celcius) on EagleXG™ glass.

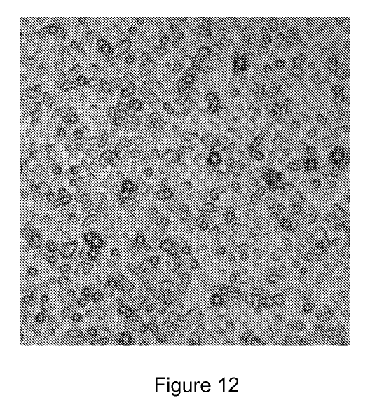

Most of the effort to date has been on the borosilicate microspheres on EagleXG™. Some experiments were recently done using soda lime microspheres on soda lime substrates. The results indicate that it is possible to obtain similar functionality with this material system. The particles were also from Potters Industries and filtered to a d50=1.9 um. A microscope photo is shown below along with scattering data for a sample sintered at 650° C. The surface morphology is quite different than for the borosilicate microspheres on EagleXG™ The scattering is similar—only 600 nm is shown but there is not very much wavelength dependence. The specular peak increases with increasing wavelength indicating a reduction in diffuse transmission with increasing wavelength. FIG. 12 is an optical microscope image of soda lime microspheres (d50=1.9 microns, 650 degrees Celcius) on EagleXG™ glass.

What is claimed is:

1. A coating method comprising:
providing a coating mixture comprising inorganic structures and a liquid carrier;
forming a coating layer of the coating mixture on a surface of a liquid subphase;
immersing at least a portion of a substrate in the liquid subphase;
separating the substrate from the liquid subphase to transfer at least a portion of the coating layer to the substrate to form a coated substrate; and
heating at least a portion of the coated substrate.

2. The method according to claim 1, wherein the substrate is an inorganic substrate and comprises a material selected from a glass, a ceramic, a glass ceramic, sapphire, silicon carbide, a semiconductor, and combinations thereof.

3. The method according to claim 1, wherein the substrate is an organic substrate and comprises a material selected from a polymer, polystyrene, polymethylmethacrylate, a thermoplastic polymer, a thermoset polymer, and combinations thereof.

4. The method according to claim 1, wherein the inorganic structures comprise spheres, microspheres, bodies, particles, aggregated particles, or combinations thereof.

5. The method according to claim 1, wherein the inorganic structures comprise a material selected from a glass, a ceramic, a glass ceramic, sapphire, silicon carbide, a semiconductor, and combinations thereof.

6. The method according to claim 1, wherein heating comprises sintering at least a portion of the inorganic structures.

7. The method according to claim 1, further comprising affecting the hydrophobicity of the inorganic structures prior to forming the coating layer.

8. The method according to claim 1, wherein the angle between adjacent inorganic structures after heating is greater than 90 degrees.

9. The method according to claim 1, wherein the coating layer has a substantially unitary direction of flow toward the substrate.

10. The method according to claim 1, wherein the substrate comprises one or more layers.

11. The method according to claim 1, wherein separating the substrate from the liquid subphase to transfer at least a portion of the coating layer to the substrate to form a coated substrate comprises forming a monolayer of the inorganic structures on the substrate.

12. The method according to claim 1, comprising heating the coated substrate as the coated substrate is being formed.

13. The method according to claim 1, wherein immersing at least a portion of an substrate in the liquid subphase comprises immersing at least a portion of the substrate in the coating layer.

14. A photovoltaic device comprising the coated substrate made according to the method of claim 1.

15. The device according to claim 14, further comprising
a conductive material adjacent to the substrate; and
an active photovoltaic medium adjacent to the conductive material.

16. The device according to claim 14, wherein the conductive material is a transparent conductive film.

17. The device according to claim 16, wherein the transparent conductive film comprises a textured surface.

18. The device according to claim 14, wherein the active photovoltaic medium is in physical contact with the transparent conductive film.

19. The device according to claim 14, further comprising a counter electrode in physical contact with the active photovoltaic medium and located on an opposite surface of the active photovoltaic medium as the conductive material.

20. A light emitting device or an optical diffuser comprising the coated substrate made according to the method of claim 1.

21. A coating method comprising:
providing a coating mixture comprising structures and a liquid carrier;
forming a coating layer of the coating mixture on a surface of a liquid subphase;
immersing at least a portion of a substrate in the liquid subphase;
separating the substrate from the liquid subphase to transfer at least a portion of the coating layer to the substrate to form a coated substrate; and
heating at least a portion of the coated substrate.

22. The method according to claim 21, wherein the substrate is inorganic, organic, or combinations thereof.

23. The method according to claim 21, wherein the structures are inorganic, organic, or combinations thereof.

24. An article comprising a sintered monolayer of structures selected from spheres, microspheres, bodies, particles, aggregated particles, and combinations thereof on a substrate.

25. The article according to claim 24, wherein the structures are fused to a surface of the substrate.
